(19) United States
(12) Patent Application Publication
(10) Pub. No.: US 2024/0076800 A1
(43) Pub. Date: Mar. 7, 2024

(54) SINGLE CRYSTAL PULLING APPARATUS AND METHOD FOR PULLING SINGLE CRYSTAL

(71) Applicant: SHIN-ETSU HANDOTAI CO., LTD., Tokyo (JP)

(72) Inventors: Hiroyuki KAMADA, Nishigo-mura (JP); Kiyotaka TAKANO, Annaka-shi (JP)

(73) Assignee: SHIN-ETSU HANDOTAI CO., LTD., Tokyo (JP)

(21) Appl. No.: 18/272,253

(22) PCT Filed: Nov. 22, 2021
(86) PCT No.: PCT/JP2021/042776

§ 371 Date: Jul. 13, 2023

(30) Foreign Application Priority Data
Jan. 26, 2021 (JP) 2021-010298

(51) Int. Cl. C30B 30/04; C30B 15/20; C30B 29/06

(52) U.S. Cl. CPC C30B 30/04; C30B 15/20; C30B 29/06

(57) ABSTRACT

A single crystal pulling apparatus includes: a pulling furnace having a central axis; and magnetic field generating apparatus around the pulling furnace and having coils, for applying a horizontal magnetic field to molten semiconductor raw material to suppress convection in crucible, in which, main coils and sub-coils are provided, as the main coils, two pairs of coils arranged facing each other are provided, two coil axes thereof are included in the same horizontal plane, a center angle α between the two coil axes sandwiching the X-axis, which is a magnetic force line direction on the central axis in the horizontal plane, is 100 degrees or more and 120 degrees or less, as the sub-coils, a pair of superconducting coils arranged to face each other is provided and its one coil axis is aligned with the X-axis, and current values of the main coils and the sub-coils can be set independently.

### TECHNICAL FIELD

The present invention relates to an apparatus and a method for pulling a single crystal such as a silicon single crystal used as a semiconductor substrate, and more particularly, it also relates to a single crystal pulling apparatus and a single crystal pulling method according to a horizontal magnetic field application Czochralski method (HMCZ method).

### BACKGROUND ART

Semiconductors such as silicon and gallium arsenide are composed of single crystals and are used for memory devices or the like of small to large computers, and there is a demand for large-capacity, low-cost, and high-quality storage devices.

The Czochralski method, as a main method of producing silicon single crystals, is a producing method in which a silicon raw material in a quartz crucible is melted to form a melt, a seed crystal is brought into contact with the melt, and a single crystal is obtained by pulling it up while rotating it. At present, the magnetic field applied CZ method (hereinafter referred to as the “MCZ method”) that suppresses convection by applying a magnetic field to the melt is the mainstream for producing large diameter crystals with a diameter of 300 mm (12 inches) or more. Conductive fluids such as silicon melt can suppress convection by applying a magnetic field. By suppressing the convection, the temperature fluctuation of the melt can be reduced, and stable crystal growth can be achieved in terms of both operation and quality.

Here, the convection suppression mechanism of the MCZ method will be described. If a vertical flow occurs in the melt due to thermal convection or the like, an electric field is generated in the horizontal direction perpendicular to both the magnetic field and the convection according to Fleming's right-hand rule. When an induced current flows due to this electric field, a Lorentz force is generated according to Fleming's left-hand rule. The direction of this force is the opposite direction of the flow that is first generated, and convection is suppressed.

However, in the case of the HMCZ method in which a horizontal magnetic field is applied, in the region where the quartz crucible wall surface and magnetic force lines are parallel, since quartz is an insulator, no induced current flows and convection is not suppressed. Here, FIG. 13 shows a plan view of the arrangement of a pair of superconducting coils (coils) in a conventional single crystal pulling apparatus 110. As shown in FIG. 13, in case of a coil arrangement such that one coil pair (104a and 104b) is simply placed inside the magnetic field generating apparatus 130 located outside the pulling apparatus 110 (109 is the central axis of the pulling furnace), it is unavoidable that there is a region where the wall surface of the crucible 106 and the magnetic force lines 107 are parallel, and convection is not sufficiently suppressed in that region. In that region, the surface flow velocity from the crucible wall surface to the crystal becomes relatively high, and the oxygen dissolved in the melt from the quartz crucible reaches the crystal without being sufficiently evaporated on the surface. As a result, the oxygen concentration in the crystal may not be lowered as intended. The above is likely to become a problem especially in the production of single crystals with a low oxygen concentration of 4×10¹⁷ atoms/cm³ or less.

As a countermeasure, for example, in the technique described in Patent Document 1, when the direction of the magnetic force line in the central axis of the pulling furnace is defined as a X axis and the direction perpendicular to it is defined as a Y axis, it specifies the shape of the magnetic flux density distribution on each axis and the relative intensity at the crucible wall. By doing so, thermal convection can be suppressed more effectively, and as a result, a crystal with a reduced oxygen concentration can be obtained. As a means for realizing such a magnetic flux density distribution, there is a pulling apparatus that defines the center angle between the respective coil axes of the two pairs of coils (the axes passing through the centers of the pairs of coils arranged opposite to each other) is disclosed.

### CITATION LIST

### Patent Literature

Patent Document 1: Japanese Patent No. 6436031
Patent Document 2: JP 2019-196289 A
Patent Document 3: JP 2004-051475 A
Patent Document 4: JP 2004-189559 A

### SUMMARY OF INVENTION

### Technical Problem

With the pulling apparatus having the magnetic flux density distribution described in Patent Document 1, it is possible to grow a single crystal with a low oxygen concentration and suppressed growth striations. However, in order to achieve such a magnetic flux density distribution, it is necessary to arrange the coils so as to bend the magnetic force lines, so compared to a coil arrangement with less bending of the magnetic force lines, the central magnetic flux density with respect to the coil current value becomes smaller. Therefore, it can be said to be inefficient from the viewpoint of the magnetic flux density on the central axis (central magnetic flux density).

It is known that a defect-free region single crystal can be obtained by controlling the ratio V/G between the crystal pulling speed V and the temperature gradient G in the crystal in the direction of the pulling axis in the vicinity of the crystal growth interface to an appropriate range. To increase the temperature gradient (G_ctr) in the pulling axial direction at the crystal center, it is effective to increase the central magnetic flux density. If G_ctr can be increased, the pulling speed V for obtaining a defect-free region single crystal can be increased, making it possible to grow a defect-free region single crystal more efficiently.

Conversely, under conditions where the central magnetic flux density is low, G_ctr is also small, and the growth efficiency of defect-free crystals is reduced. Furthermore, when G_ctr becomes smaller than a certain threshold, even if V is reduced in order to make Void defects at the crystal center defect-free, the latent heat (solidification heat) per unit of time generated on the solid-liquid interface due to the reduced V is reduced, further reducing G_ctr. As a result, in order to make the center of the crystal completely defect-free, V must be greatly lowered. As a result, the balance with the temperature gradient G_edg in the direction of the pulling axis on the outer circumference of the crystal cannot be kept, and a defect-free region single crystal may not be obtained in the entire in-plane region.

The above phenomenon can be a problem regardless of the oxygen concentration when growing defect-free region single crystals. Especially in the growth of normal oxygen concentration of 8×10¹⁷ atoms/cm³ or more, which is usual in products for memory or the like, there is a problem that productivity is inferior to the case of other coil arrangements (or production is not possible) in the technique of Patent Document 1. The reason for this is that if the oxygen concentration specification is 8×10¹⁷ atoms/cm³ or more, it is not necessary to actively lower the oxygen concentration using a technique such as Patent Document 1, and a single crystal can be produced at a higher pulling speed by a coil arrangement that the central magnetic flux density can be effectively increased as shown in FIG. 13.

The present invention has been made in view of the above and it is an object of the present invention to provide a single crystal pulling apparatus and a method for producing a single crystal capable of producing a low oxygen concentration single crystal and growing a normal oxygen concentration defect-free region single crystal at high speed with the same apparatus.

### Solution to Problem

In order to achieve the above object, the present invention provides a single crystal pulling apparatus comprising: a pulling furnace in which a heating heater and a crucible containing a molten semiconductor raw material are arranged and which has a central axis; and a magnetic field generating apparatus provided around the pulling furnace and having superconducting coils, for applying a horizontal magnetic field to the molten semiconductor raw material by energizing the superconducting coils to suppress convection of the molten semiconductor raw material in the crucible,
wherein,
as the superconducting coils of the magnetic field generating apparatus, main coils and sub-coils are provided,
as the main coils, two pairs of superconducting coils arranged facing each other are provided,
when an axis passing through the centers of a pair of superconducting coils arranged facing each other is defined as a coil axis, two coil axes of the two pairs of superconducting coils, which are the main coils, are included in the same horizontal plane,
when a magnetic force line direction on the central axis in the horizontal plane is defined as a X-axis, the main coils are arranged such that a center angle α between the two coil axes sandwiching the X-axis is 100 degrees or more and 120 degrees or less,
as the sub-coils, a pair of superconducting coils arranged to face each other is provided and the sub-coils are arranged such that a coil axis of the pair of superconducting coils, which are the sub-coils, is aligned with the X-axis, and
current values of the main coils and the sub-coils can be set independently.

If the magnetic field generating apparatus of the single crystal pulling apparatus is configured as described above, by setting the current values of the main coils and the sub-coils to appropriate values according to the product specification to be produced (pulled), it can be a single crystal pulling apparatus which enables single crystal production of low oxygen concentration and high speed growth of a defect-free region single crystal having a normal oxygen concentration.

At this time, the main coils and the sub-coils can be any one of a racetrack shape, an elliptical shape, and a saddle shape curved in the same direction as the outer shape of the pulling furnace, and
a height in a vertical direction can be shorter than a width in a horizontal direction.

With a coil of such a shape, it is possible to displace the horizontal position of the coil axis toward the end (upper end side or lower end side) of the housing of the magnetic field generating apparatus compared to the case where a circular coil is used and the settable range of the horizontal height (height position) of the coil axis can be expanded. This also makes it possible to produce single crystals with a lower oxygen concentration.

Further, the main coils can have a saddle shape curved with a larger curvature than a shape along the outer shape of the pulling furnace, and
the ratio of the curvature of the saddle-shaped main coils to a curvature of the shape along the outer shape of the pulling furnace can be 1.2 or more and 2.0 or less.

With such a structure, it is possible to produce a single crystal with a lower oxygen concentration than in the case of using a saddle-shaped coil curved along the outer shape of the pulling furnace.

Further, the magnetic field generating apparatus can comprise an elevating device capable of moving up and down in a vertical direction.

With such a structure, it is possible to select a suitable magnetic field height (height position of the coil axis) for each target value of the oxygen concentration of the single crystal to be produced.

The present invention also provides a method for pulling a single crystal, which comprises pulling a semiconductor single crystal using the single crystal pulling apparatus described above.

With such a single crystal pulling method, it is possible to produce both low oxygen concentration single crystals and normal oxygen concentration defect-free region single crystals with high speed growth with single apparatus of single crystal pulling apparatus.

At this time, the semiconductor single crystal to be pulled can be a defect-free region single crystal.

The present invention can grow defect-free region single crystals (especially those with normal oxygen concentration) at high speed.

### Advantageous Effects of Invention

As described above, according to the apparatus for pulling a single crystal and the method for pulling a single crystal of the present invention, a single apparatus for pulling a single crystal can produce both a single crystal with a low oxygen concentration and can grow a defect-free region single crystal with a normal oxygen concentration at a high speed.

### BRIEF DESCRIPTION OF DRAWINGS

FIG. 1 is a schematic diagram showing an example of a single crystal pulling apparatus of the present invention;

FIG. 2 is a plan view showing an example of the arrangement of three pairs of coils in the apparatus of the present invention;

FIG. 3 is a graph showing an example of the relationship between the relative current value (Im) of the main coils/the relative current value (Is) of the sub-coils and the central magnetic flux density in three pairs of coils;

FIG. 4 is a graph showing an example of B⊥ distribution in the crucible circumferential direction with respect to Im Is in a three pairs of coils;

FIG. 5 is a graph showing an example of B⊥ distribution in the crucible circumferential direction when the central magnetic flux density is fixed at 1000 G and the current ratio between Im and Is is changed in three pairs of coils;

FIG. 6 is a side view showing an example of a racetrack shaped coil;

FIG. 7 is a side view showing an example of an elliptical shaped coil;

FIG. 8 is a perspective view showing an example of a saddle shape curved in the same direction as the outer shape of the pulling furnace;

FIG. 9 is a graph showing the relationship between the B⊥ distribution and the circumferential angle when Im:Is=1:0 when the coil shape is saddle-shaped and the curvature of the main coils are changed;

FIG. 10 is a plan view showing an example of an arrangement of three pairs of coils having a saddle shape (curving along the outer shape of the pulling furnace);

FIG. 11 is a graph comparing the relative values of the growth rates of defect-free region single crystals in Example 1 and Comparative Example 1;

FIG. 12 is a plan view showing an example of an arrangement of three pairs of coils having a saddle shape (the main coils are curved with a curvature larger than the outer shape of the pulling furnace, and the sub-coils are curved along the outer shape of the pulling furnace);

FIG. 13 is a plan view showing an example of an arrangement of a pair of coils in a conventional single crystal pulling apparatus;

FIG. 14 is a plan view showing an example of an arrangement of two pairs of coils in a conventional single crystal pulling apparatus;

FIG. 15 is a diagram showing an example of the relationship between the inter-coil-axis angle α and the central magnetic flux density in two pairs of coils;

FIG. 16 is a graph showing an example of B⊥ distribution in the crucible circumferential direction in a pair of coils; and

FIG. 17 is a graph showing an example of B⊥ distribution in the crucible circumferential direction in two pairs of coils.

### DESCRIPTION OF EMBODIMENTS

The present invention will be described in detail below with reference to the drawings, but the present invention is not limited thereto.

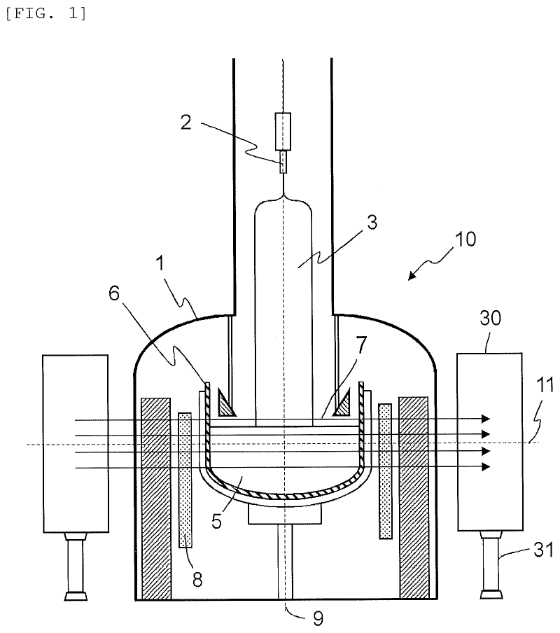

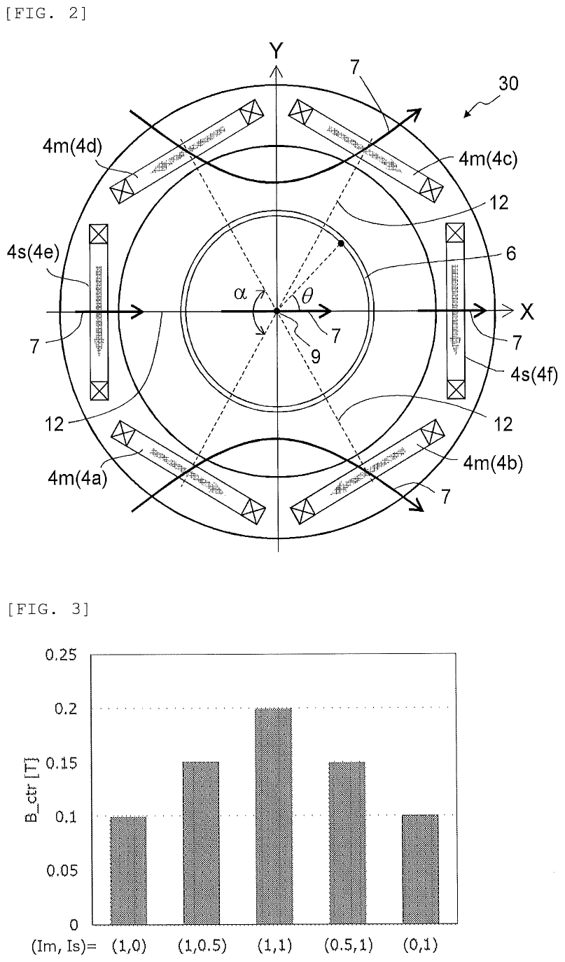

An example of the single crystal pulling apparatus 10 of the present invention is shown in FIG. 1. Also shown in FIG. 2 is the arrangement of the three pairs of coils in the apparatus of the present invention.

The single crystal pulling apparatus 10 shown in FIG. 1 is based on the MCZ method (more specifically, the HMCZ method), and comprises a pulling furnace in which a heating heater 8 and a quartz crucible 6 containing a molten semiconductor raw material (hereinafter referred to as “melt”) 5 are arranged and which has a central axis 9 of rotation of the crucible 6 (which is also the central axis of the pulling furnace 1) and a magnetic field generating apparatus 30 having superconducting coils (hereinafter also referred to as “coils”) provided around the pulling furnace 1. A horizontal magnetic field is applied to the melt 5 by energizing the superconducting coils to pull the single crystal 3 (for example, a silicon single crystal) in the pulling direction while suppressing the convection of the melt in the crucible.

As for the coils, as shown in FIG. 2, main coils 4m and sub-coils 4s are provided. As for the main coils 4m, two pairs of coils arranged to face each other are provided (a pair of 4a and 4c and a pair of 4b and 4d). As for the sub-coils 4s, a pair of coils arranged to face each other is provided (a pair of 4e and 4f).

Here, when an axis passing through the centers of a pair of coils arranged facing each other is assumed to be a coil axis 12, the coils 4a to 4f are arranged so that two coil axes in two pairs of coils that are the main coils 4m and a coil axis in a pair of coils that is the sub-coils 4s are all included in the same single horizontal plane 11.

Moreover, regarding the main coils 4m, when the direction of the magnetic force line on the central axis 9 in the horizontal plane 11 is defined as the X-axis, the main coils 4m are arranged such that the center angle α between the two coil axes of the main coils 4m sandwiching the X-axis is 100 degrees or more to 120 degrees or less. By arranging the main coils 4m so that the center angle α is 120 degrees or less, the adjacent main coils 4m (that is, 4a and 4b, 4c and 4d) do not collide with each other, and the angle α is 100 degrees or more, in the case of growing a single crystal with a low oxygen concentration, it is possible to effectively reduce the oxygen concentration significantly. On the other hand, the sub-coils 4s are arranged such that its single coil axis and the X-axis are aligned.

In the example shown in FIG. 2, the coil 4e is arranged between the coils 4a and 4d, and the coil 4f is arranged between the coils 4c and 4b.

It should be noted that reference numeral 7 indicates lines of magnetic force.

Hereinafter, the single crystal pulling apparatus 10 of the present invention (especially the coils) will be described in more detail while being compared with the configuration of a conventional single crystal pulling apparatus.

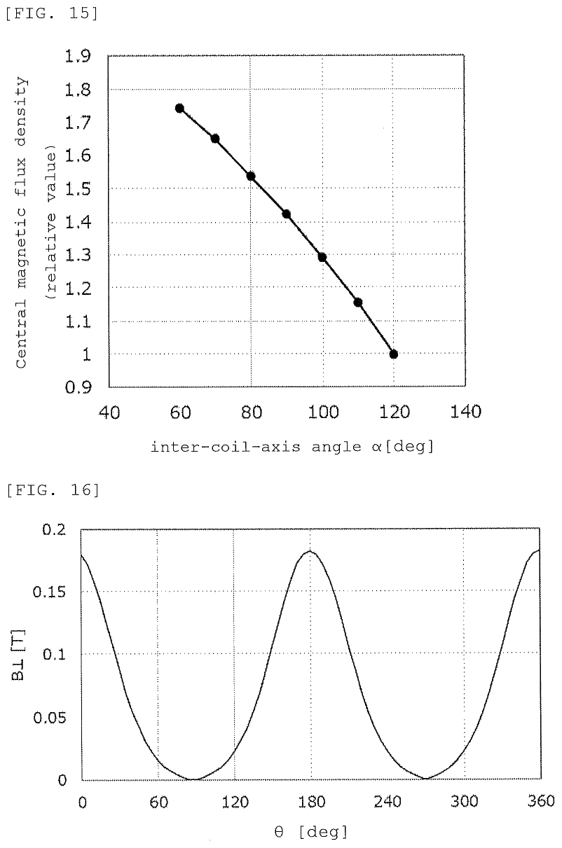

First, FIG. 14 shows a plan view in which two pairs of coils (pair of 204a and 204c, pair of 204b and 204d) are arranged in a conventional single crystal pulling apparatus 210. As shown in FIG. 14, if the center angle α (209 is the central axis) in FIG. 14 is in the range of 100 to 120 degrees, it becomes the coil arrangement disclosed in Patent Document 1.

FIG. 15 shows relative value of the central magnetic flux density when α is changed while the current value of each coil is kept constant. The larger the α, the smaller the relative value of the central magnetic flux density. This is because the larger the α, the larger the angle (α/2) between each coil axis and the X-axis, and the smaller the X-direction component of the magnetic force lines generated from each coil. Thus, considering the central magnetic flux density as a reference, the coil arrangement disclosed in Patent Document 1 cannot be said to be efficient. As a result, the growth rate to be a defect-free region single crystal becomes low or it may become impossible to obtain a defect-free region single crystal in some cases.

In view of this point, in the present invention, as shown in FIG. 2 and as described above, the following is devised: another pair of coils (sub-coils 4s: pair of 4e and 4f) is added so that the coil axis 12 coincides with the X axis; and the current value of the sub-coils 4s can be set independently to the two pairs of coils before the addition (main coils 4m: pair of 4a and 4c, pair of 4b and 4d). For example, the main coils 4m and the sub-coils 4s are separately wired, and by setting a computer or the like, it is possible to configure such that they can be energized independently at desired current values.

With such a configuration, by setting the current value of the sub-coils to a certain high value, the central magnetic flux density can be improved, and the growth rate of the defect-free region single crystal can be increased. In addition, when producing crystals with a low oxygen concentration, by setting the current value of the sub-coils to zero or a low value, a magnetic field distribution similar to that in Patent Document 1 can be generated, and it is possible that the production of crystals with a low oxygen concentration can be performed.

In this way, by adopting a configuration in which the current values of the main coils and the sub-coils can be set independently of each other, the convection suppression force by the magnetic field can be controlled more finely, and it becomes possible that single crystals with more diverse qualities can be produced.

The increase in the growth rate of a defect-free region single crystal by increasing the central magnetic flux density has been confirmed to be effective in actual crystal production, and its effect is considered as follows.

First, when the central magnetic flux density is low, convection is not strongly suppressed by the magnetic field, so the flow path in the melt becomes relatively simple that it rises at the crucible side wall, flows toward the center on the melt surface, and descends at the center. When the temperature distribution is such that the crucible bottom is lower in temperature than the side wall, natural convection from the bottom to the side wall does not occur. It is considered that the above flow path circulates only in upper region of side wall and the low-temperature melt accumulates at the bottom. If such a low-temperature melt exists directly below the solid-liquid interface, heat is not sufficiently supplied to the solid-liquid interface, so the solid-liquid interface tends to be convex downward (to the melt side). It is considered that the intra-crystal temperature gradient G_ctr in the pulling axis direction of the crystal center is lowered.

On the other hand, when the central magnetic flux density is high, even though the convection is strongly suppressed by the magnetic field, there is also forced convection due to crystal rotation, so a stable flow path is not formed, and the convection immediately below the solid-liquid interface is considered to be particularly complicated. As a result, the melt at the bottom is agitated, the temperature of the melt immediately below the interface is uniformed, and heat is supplied to the solid-liquid interface compared to when the central magnetic flux density is low, so that G_ctr increases.

Next, the relationship between the magnetic field distribution and the oxygen concentration, which is a particular problem in the production of low oxygen concentration crystals, will be described in more detail.

As with the convection suppression mechanism by the magnetic field described above, the force that suppresses the thermal convection of the melt 5 does not work in the region where the magnetic force lines are parallel to the crucible wall. For this reason, the magnetic flux density component was decomposed into two components; the magnetic flux density component perpendicular to the inner wall of the crucible (hereinafter referred to as “B⊥”) and the magnetic flux density component parallel to the inner wall of the crucible (hereinafter referred to as “B//”), only the B⊥ component contributes to the suppression of convection. This is described in detail in Patent Document 2.

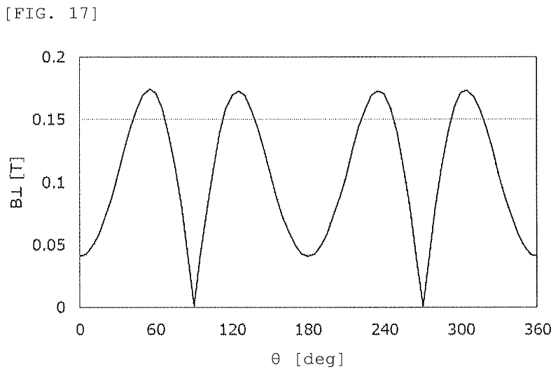

FIG. 16 shows B⊥ distribution in the crucible circumferential direction when the central magnetic flux density is 1000 G in FIG. 13, and FIG. 17 shows B⊥ distribution in the crucible circumferential direction when the center angle α between the coil axes is 120° and the central magnetic flux density is 1000 G in FIG. 14. θ on the horizontal axis is the angle formed by the line segment connecting the points on the inner circumference of the crucible and the central axes 109 or 209 with the X axis, as shown in FIGS. 13 and 14.

B⊥ is zero at the positions of θ=90 and 270° in both the coil arrangements of FIGS. 13 and 14, it can be seen that the convection suppression force does not work. This is because the coil arrangement is symmetrical about the Y axis, so the Y component always becomes zero at a point on the Y axis. As long as they are Y-axis symmetrical, they cannot be avoided in any arrangement. However, in FIG. 14 (FIG. 17), the rise from zero is steeper than in FIG. 13 (FIG. 16). Since the range of values near zero is very narrow, it can be said that the convection is substantially sufficiently suppressed. Thus, it can be said that the coil arrangement of FIG. 14 is suitable for suppressing convection in the entire melt.

Now consider in detail the magnetic field distribution in the coil arrangement of the present invention (FIG. 2). In the following description, the results for the case where the main coils and sub-coils have the same shape and α=120° are shown, but the present invention is not limited to this.

FIG. 3 shows the relationship between the relative current value (Im) of the main coils, the relative current value (Is) of the sub-coils, and the central magnetic flux density B_ctr. Regarding the relative current value, the current value at which the central magnetic flux density becomes 1000 G when the current is applied only to the four main coils is set to 1. The results of changing the current values of the main coils and sub-coils in the ranges of 0, 0.5 and 1 are shown.

As can be read from FIG. 3, the magnitude of the central magnetic flux density generated by the main coils and sub-coils each contributes independently, and the overall central magnetic flux density can be obtained by summing the central magnetic flux densities obtained from the current values of the main coils and sub-coils respectively. Note that the central magnetic flux density is 1000 G as a result of (Im, Is)=(0, 1) where a current value of 1 is passed only through the sub-coils. This is because that the angle between the main coils and the X-axis is 60°, the angle between the sub-coils and the X-axis is 0°, the sum of the magnetic flux densities of the four main coils (4×B×cos(60°)) and the sum of the two sub-coils (2×B×cos(0°)) are equal.

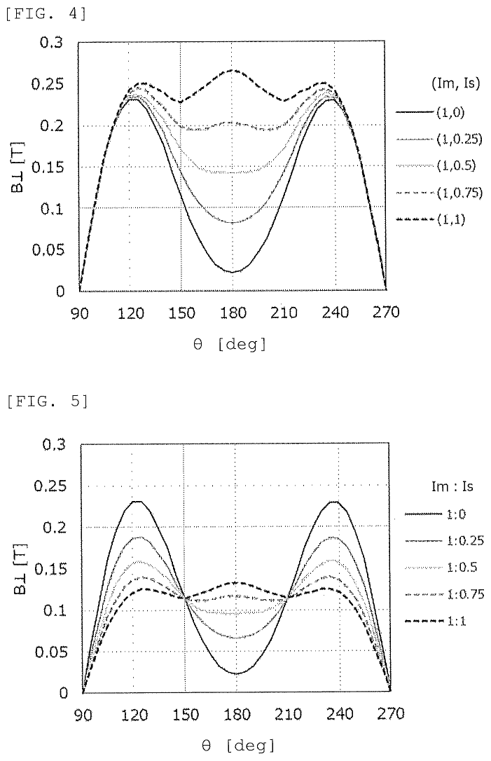

FIG. 4 shows the calculation results of the B⊥ distribution in a range of 90° to 270° when Im is fixed at 1 and Is is varied.

The B⊥ distribution when Is is 0 or 0.25 is similar to the distribution of the two-pair coils (FIG. 17), and crystals with low oxygen concentration can be produced under these conditions. If Is is further increased from here, B⊥ around θ=180° increases, and the B⊥ distribution becomes more uniform. With such a B⊥ distribution, the convection of the entire melt is sufficiently suppressed, so at first glance it seems to work more favorably for the production of low oxygen concentration crystals.

However, when crystals were actually produced, it was found that, for example, under conditions such as (Im, Is)=(1, 1), the oxygen concentration did not always decrease, and in some cases the oxygen concentration increased. This is because convection on the crucible wall is generally suppressed, so that the melt in contact with the crucible wall is less likely to rotate along with the crucible rotation, and the relative velocity between the crucible and the melt increases to accelerate oxygen dissolution to melt. It is also conceivable that heat transport is reduced by suppressing convection, and the temperature of the crucible wall surface rises relative to the crystal, thereby promoting the dissolution of the crucible. Suppression of convection also has the effect of lowering oxygen (=lengthening the evaporation time of oxygen) by reducing the surface velocity of the melt. But under the above conditions, it is presumed that the effect of promoting oxygen dissolution works more strongly, resulting in an increase in oxygen concentration.

On the other hand, FIG. 5 shows the B⊥ distribution when the central magnetic flux density is fixed at 1000 G and the current ratio between Im and Is is changed. Im and Is in the figure are not the relative current values themselves but the ratio of the current values, for example, when Im:Is=1:1, the actual relative current value is (Im, Is)=(0.5, 0.5).

As a result of crystal production under these conditions, it was found that conditions such as Im:Is=1:1, where the current ratio of Is is large, increased the oxygen concentration compared to Im:Is=1:0. This is probably because the rise of B⊥ from 0=90° becomes gentle, so that convection is not sufficiently suppressed and the melt with insufficient oxygen evaporation reaches the crystal.

As described above, it was found that excessively increasing the current Is of the sub-coils leads to an increase in the oxygen concentration in both the case where the current value Im of the main coils is fixed and the case where the central magnetic flux density is fixed. Therefore, in order to selectively produce various specifications of crystals including low-oxygen concentration crystals, it is necessary to make Is variable and independently control the current values of Im and Is depending on the specification.

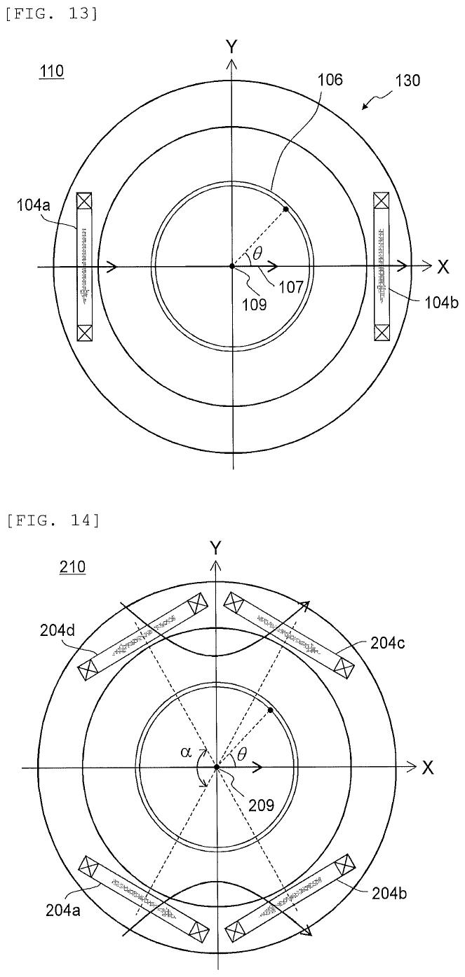

FIG. 12 of Patent Document 3 exemplifies a magnetic field generating apparatus in which three pairs of coils are arranged. This coil arrangement is similar to the present invention, but the document does not mention that the current value of the coils can be independently controlled, and the object of the invention is to generate a uniform magnetic flux density distribution. All the current values of each coil are therefore considered to be the same. Therefore, in this configuration, as described above, crystals having a low oxygen concentration cannot be produced, and therefore, there is a technical difference from the present invention.

By the way, although the shape of the main coils 4m and the sub-coils 4s in the present invention is not particularly limited, for example, they can be circular coils that are often used.

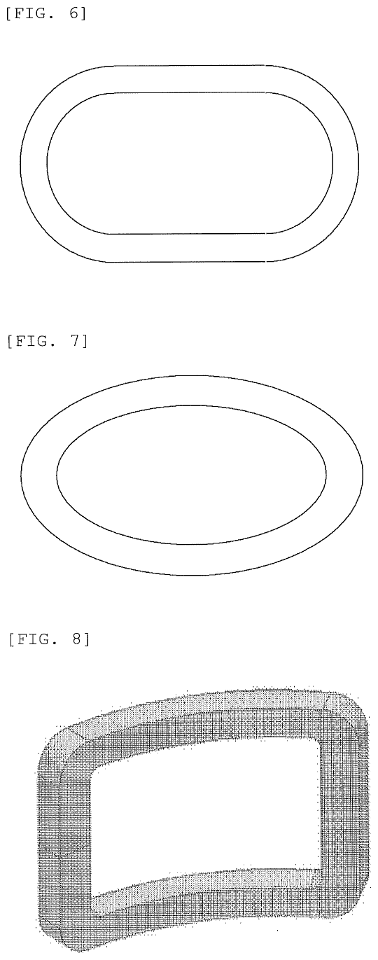

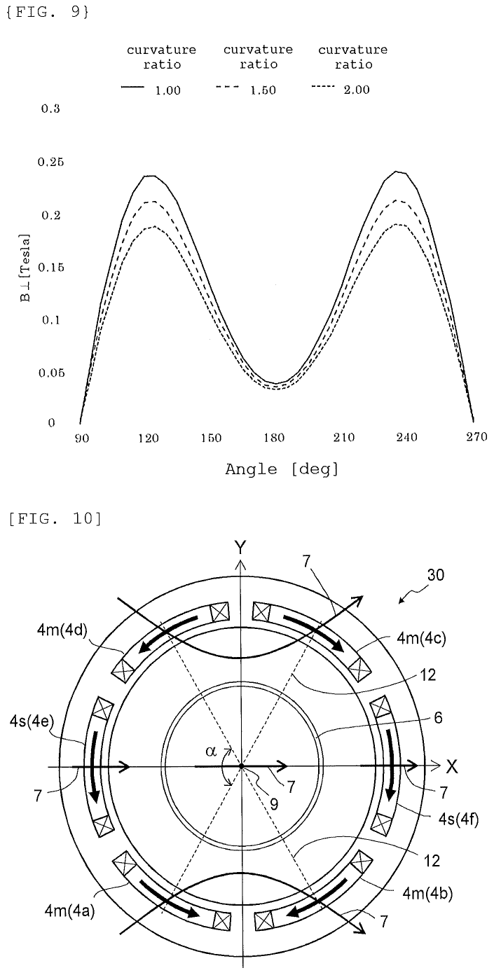

Alternatively, it can be a racetrack shape, an elliptical shape, or a saddle shape curved in the same direction as the outer shape of the pulling furnace, and the height in the vertical direction can be shorter than the width in the horizontal direction. FIGS. 6 and 7 show examples of side views of the racetrack shape and elliptical shape as described above. Further, FIG. 8 shows an example of a perspective view of the saddle shape.

As a result, compared to the case of using a circular coil, the horizontal position of the coil axis can be biased toward the end of the housing of the magnetic field generating apparatus. In other words, the height of the shape of the coil is lower than that of a circular coil, so it is easier to move to the edge side (upper end side or lower end side) of the housing, so the horizontal position of the coil axis can be set higher or lower. As shown in Patent Document 4, it is possible to control the oxygen concentration by changing the horizontal position of the coil axis. Especially, if the horizontal position of the coil axis is set high, it is advantageous when producing low oxygen concentration crystals.

As a more specific form of the saddle-shaped main coils, for example, the ratio of the curvature of the saddle-shaped main coils to the curvature of the shape along the outer shape of the pulling furnace (curvature ratio) is 1.2 or more and 2.0 or less. That is, when the curvature of the shape along the outer shape of the pulling furnace is 1, the center of the thickness of the coil has a curvature of 1.2 or more and 2.0 or less. With such a saddle shape, it is possible to produce a single crystal with a lower oxygen concentration.

FIG. 9 shows a plot of the B⊥ distribution against the circumferential angle when Im:Is=1:0 (that is, when only four main coils are energized), the coil shape is saddle-shaped and the curvature of the main coils is changed. If the curvature ratio is increased from the shape along the outer shape of the pulling furnace as a reference, B⊥ near 1250 and 235° corresponding to the vicinity of the center region of each coil is found to be relaxed. With the magnetic field distribution of the present invention, the difference in the convection suppression force between the cross section parallel to the X axis and the cross section perpendicular to the X axis is smaller than that of the conventional horizontal magnetic field. However, since the magnetic flux density component perpendicular to the crucible is particularly strong in the angular region (angular region near the coil axis in the main coils) existing 4 regions in a whole circumference, the oxygen diffusion boundary layer near the crucible wall becomes thin, so oxygen is easier to dissolve from the quartz crucible compared to other angular regions. Since the magnetic flux density away from the coil is inversely proportional to the square of the distance to the coil, it is possible to reduce the magnetic flux density in these angular regions by increasing the curvature of the coil. The proper range of the curvature ratio is preferably 1.2 or more for the effect of reducing the magnetic flux density in the angular region near the coil axis, and 2.0 or less is preferable in order to prevent the outer shape of the housing containing the coil from becoming too large and prevent the center magnetic field strength from decreasing and causing a decrease in the maximum magnetic field strength.

Further, as shown in FIG. 1, the magnetic field generating apparatus 30 can be provided with an elevating device 31 capable of moving up and down in the vertical direction. For example, the magnetic field generating apparatus 30 is preferably installed on the elevating device 31. As an example, when the coil shape is not circular and the horizontal height of the coil axis is high as described above, it is suitable for producing crystals with a low oxygen concentration, but it becomes difficult to increase the oxygen concentration. Therefore, if the magnetic field generating apparatus can be moved up and down by an elevating device, the optimal horizontal height of the coil axis can be selected according to the target oxygen concentration, and the range of compatible specifications can be expanded.

Next, an embodiment of the method for pulling a single crystal according to the present invention will be described with reference to FIG. 1. The method for pulling single crystal of the present invention uses the single crystal pulling apparatus shown in FIG. 1 described above to pull a semiconductor single crystal such as a silicon single crystal.

Specifically, a semiconductor single crystal is pulled as follows. First, in the single crystal pulling apparatus 10, a semiconductor raw material is placed in the quartz crucible 6 and heated by the heating heater 8 to melt the semiconductor raw material. Next, by energizing the superconducting coils 4a to 4f, a horizontal magnetic field generated by the magnetic field generating apparatus 30 is applied to the melt 5 to suppress convection of the melt 5 in the quartz crucible 6.

As described above, as the magnetic field generating apparatus 30, as shown in FIG. 2, two pairs of superconducting coils 4a to 4d arranged to face each other are provided so that the respective coil axes 12 are included in the same horizontal plane. Then, the main coils 4m (4a to 4d) are arranged so that the center angle α between the coil axes sandwiching the X axis is 1000 or more and 1200 or less. Moreover, a pair of superconducting coils (4e and 4f) as the sub-coils 4s is arranged so that the coil axis of the pair is aligned with the X axis. Although the coil shape is circular in FIG. 2, it may be a saddle shape shown in FIGS. 8 and 10 (plan view showing an example of an arrangement of three pairs of coils), a shape such as an elliptical shape shown in FIG. 7 and a racetrack shape shown in FIG. 6 may be used. Alternatively, the magnetic field generating apparatus 30 may be placed on the elevating device 31 so that it can be moved in the vertical direction. Since the horizontal height of the coil axis can be adjusted by changing the coil shape or using an elevating device as described above, the range of oxygen concentration that can be produced can be further expanded.

The current values of the main coils and sub-coils and the horizontal height of the coil axis of the magnetic field generating apparatus can be changed according to the target oxygen concentration and grown-in defect region of the single crystal to be produced. For example, when pulling a low oxygen concentration crystal with an oxygen concentration of 4×10¹⁷ atoms/cm³ (old ASTM) or less, it can be produced, if the current ratio Is/Im of the sub-coils to the main coils is a small ratio of about 0 to 0.25. At this time, it becomes easier to lower the oxygen concentration by making the horizontal height of the coil axis as high as possible so as to approach the vicinity of the melt surface.

In the case of producing a defect-free region single crystal with a low oxygen concentration, for example, the current ratio of the sub-coils is set to a certain extent high (eg, Is/Im=0.5), or the central magnetic flux density is increased while keeping the current ratio is 0 to 0.25. Thereby, the growth rate can be increased compared to the conventional technology. However, compared to the case where defect region is not specified, the lower limit of the oxygen concentration that can be produced is slightly increased by changing the conditions.

On the other hand, when pulling a crystal with an oxygen concentration of 8×10¹⁷ atoms/cm³ or more as a defect-free region single crystal, for example, the sub-coils ratio is increased so that the current ratio Is/Im of the sub-coils is 0.5 or more and the central magnetic flux density is increased to, for example, 2000 G or more. Thereby, it is possible to produce the crystal under the condition of a high growth rate for a defect-free region single crystal. At this time, by making the horizontal height of the coil axis downward away from the melt surface, it becomes easier to produce a crystal with a higher oxygen concentration.

As described above, after setting the coil current value and the magnetic field height suitable for the target oxygen concentration and grown-in defect region of the single crystal to be produced, next, for example, the seed crystal 2 is lowered from above the central portion of the quartz crucible 6 and gently inserted, and is pulled in the pulling direction at a predetermined speed while rotating the seed crystal 2 by a pulling mechanism (not shown). As a result, a single crystal grows in the solid/liquid boundary layer, and a semiconductor single crystal 3 is produced.

With such a single crystal pulling method, it is possible to produce defect-free region single crystals at a high pulling speed and to produce single crystals with various oxygen concentration ranges including low oxygen concentration with a single apparatus.

### EXAMPLE

The present invention will be described in more detail below with reference to Examples and Comparative Example of the present invention, but the present invention is not limited to these.

### Example 1

In the single crystal pulling apparatus 10 shown in FIG. 1, as the magnetic field generating apparatus 30, it is configured that three pairs of circular coils have the structure shown in FIG. 2 (as main coils, pairs of 4a and 4c, and 4b and 4d, as sub-coils, a pair of 4e and 4f), and a center angle α between the coil axes sandwiching the X-axis is of 120°. Using such a single crystal pulling apparatus, a silicon single crystal was pulled under the following conditions. The target oxygen concentration at this time was 9×10¹⁷ atoms/cm³.

Crucible used: diameter 800 mm
Charge amount of semiconductor raw materials: 400 kg
Single crystal to be grown: diameter 306 mm
Central magnetic flux density: 2000 G
Coil current ratio (main:sub): 1:1
Single crystal rotation speed: 11 rpm
Crucible rotation speed: 0.5 rpm
Horizontal height of coil axis: 200 mm below the melt surface

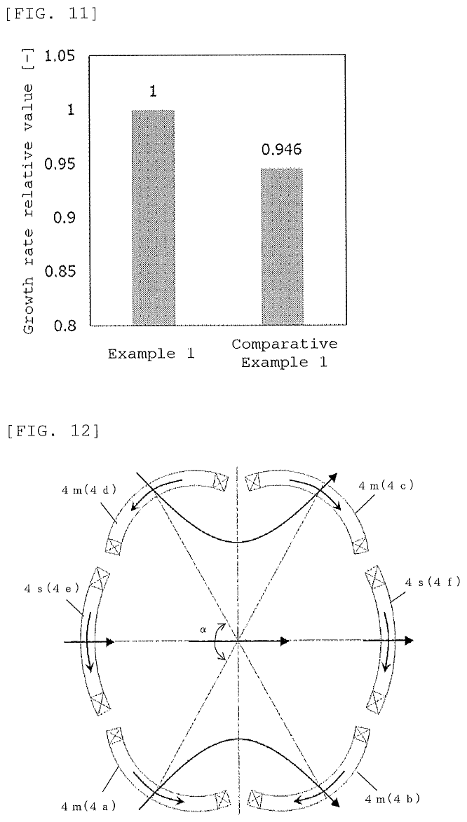

In the semiconductor single crystal grown in this way, the growth rate of the defect-free region single crystal was obtained. The resulting relative values are shown in FIG. 11.

### Comparative Example 1

Except for using a magnetic field generating apparatus with two pairs of circular coils (a pair of 204a and 204c and a pair of 204b and 204d) and having a center angle α of 120° between the coil axes sandwiching the X-axis shown in FIG. 14, a silicon single crystal was pulled under the same conditions as in Example 1 using a single crystal pulling apparatus having the same configuration as in Example 1. Regarding this condition, in Comparative Example 1, the coils are two pairs as described above, and there is no distinction between main coils and sub-coils, and the central magnetic flux density by the two pairs is 2000 G as in Example 1.

FIG. 11 shows the relative values of the growth rate of the grown silicon single crystal to become a defect-free region single crystal.

As comparing the results of Example 1 using the single crystal pulling apparatus of the present invention and Comparative Example 1 using the conventional single crystal pulling apparatus, as shown in FIG. 11, the growth rate of a defect-free region single crystal in Comparative Example 1 was 5.4% lower than that in Example 1. As described above, it turns out that the apparatus of the present invention can pull a defect-free region single crystal having a normal level of oxygen concentration at a higher speed than when the conventional apparatus having only two pairs of coils shown in FIG. 14 is used and productivity can be improved.

### Example 2

Using the magnetic field generating apparatus of Example 1, a silicon single crystal was pulled under the same conditions as in Example 1 except for the conditions shown below.

Central magnetic flux density: 1000 G
Coil current ratio (main:sub): 1:0.25
Crucible rotation speed: 0.03 rpm
Horizontal height of coil axis: 120 mm below the melt surface

When the oxygen concentration of the grown silicon single crystal was investigated, it was 3.2 to 3.9×10¹⁷ atoms/cm³.

### Example 3

A silicon single crystal was pulled under the same conditions as in Example 2, except that the coil current ratio (main:sub) was 1:1.

When the oxygen concentration of the grown silicon single crystal was investigated, it was 4.0 to 4.9×10¹⁷ atoms/cm³.

Comparing Example 2 and Example 3, Example 2 was able to obtain a silicon single crystal with a lower oxygen concentration than Example 3. Only by independently setting the current values of the main coils and the sub-coils to set the ratio of them appropriately, it is possible to obtain not only the single crystal with a slightly low level of oxygen concentration as in Example 3, but also the single crystals with even lower oxygen concentrations of less than 4.0×10¹⁷ atoms/cm³ as in Example 2. As described above, the single crystal pulling apparatus and pulling method of the present invention can easily pull single crystals with various levels of oxygen concentrations.

### Example 4

A magnetic field generating apparatus with three pairs of saddle-shaped coils and having a center angle α of 120° between the coil axes sandwiching the X-axis shown in FIG. 10 was used, and horizontal height of coil axis was set to be the same as melt surface, a silicon single crystal was pulled under the same other conditions as in Example 2.

When the oxygen concentration of the grown silicon single crystal was investigated, it was 2.5 to 3.2×10¹⁷ atoms/cm³. A silicon single crystal with an even lower oxygen concentration than in Example 2 was obtained by using saddle-shaped coils and elevating horizontal height of the coil axis.

### Example 5

FIG. 12 shows an example of arrangement of three pairs of coils having a saddle-shaped coil shape. More specifically, it is a mode that the main coils are curved with a curvature larger than the outer shape of the pulling furnace (curvature ratio 1.8), and the sub-coils are curved along the outer shape of the pulling furnace. A magnetic field generating apparatus having three pairs of saddle-shaped coils as shown in FIG. 12 was used, and a silicon single crystal was pulled under the same conditions as in Example 4 except for the conditions described above.

When the oxygen concentration of the grown silicon single crystal was investigated, it was found to be 2.2 to 3.0×10¹⁷ atoms/cm³. A silicon single crystal with an even lower oxygen concentration than in Example 4 was obtained by using saddle-shaped coils having a large curvature and elevating horizontal height of the coil axis.

The present invention is not limited to the above embodiments. The above-described embodiments are just examples, and any examples that substantially have the same configuration and demonstrate the same functions and effects as those in the technical concept disclosed in the claims of the present invention are included in the technical scope of the present invention.

1-6. (canceled)

7. A single crystal pulling apparatus comprising: a pulling furnace in which a heating heater and a crucible containing a molten semiconductor raw material are arranged and which has a central axis; and a magnetic field generating apparatus provided around the pulling furnace and having superconducting coils, for applying a horizontal magnetic field to the molten semiconductor raw material by energizing the superconducting coils to suppress convection of the molten semiconductor raw material in the crucible,
wherein,
as the superconducting coils of the magnetic field generating apparatus, main coils and sub-coils are provided,
as the main coils, two pairs of superconducting coils arranged facing each other are provided,
when an axis passing through the centers of a pair of superconducting coils arranged facing each other is defined as a coil axis, two coil axes of the two pairs of superconducting coils, which are the main coils, are included in the same horizontal plane,
when a magnetic force line direction on the central axis in the horizontal plane is defined as a X-axis, the main coils are arranged such that a center angle α between the two coil axes sandwiching the X-axis is 100 degrees or more and 120 degrees or less,
as the sub-coils, a pair of superconducting coils arranged to face each other is provided and the sub-coils are arranged such that a coil axis of the pair of superconducting coils, which are the sub-coils, is aligned with the X-axis, and
current values of the main coils and the sub-coils can be set independently.

8. The single crystal pulling apparatus according to claim 7,
wherein the main coils and the sub-coils are
any one of a racetrack shape, an elliptical shape, and a saddle shape curved in the same direction as the outer shape of the pulling furnace, and
a height in a vertical direction is shorter than a width in a horizontal direction.

9. The single crystal pulling apparatus according to claim 7,
wherein the main coils have a saddle shape curved with a larger curvature than a shape along the outer shape of the pulling furnace, and
the ratio of the curvature of the saddle-shaped main coils to a curvature of the shape along the outer shape of the pulling furnace is 1.2 or more and 2.0 or less.

10. The single crystal pulling apparatus according to claim 8,
wherein the main coils have a saddle shape curved with a larger curvature than a shape along the outer shape of the pulling furnace, and
the ratio of the curvature of the saddle-shaped main coils to a curvature of the shape along the outer shape of the pulling furnace is 1.2 or more and 2.0 or less.

11. The single crystal pulling apparatus according to claim 7, wherein the magnetic field generating apparatus comprises an elevating device capable of moving up and down in a vertical direction.

12. The single crystal pulling apparatus according to claim 8, wherein the magnetic field generating apparatus comprises an elevating device capable of moving up and down in a vertical direction.

13. The single crystal pulling apparatus according to claim 9, wherein the magnetic field generating apparatus comprises an elevating device capable of moving up and down in a vertical direction.

14. The single crystal pulling apparatus according to claim 10, wherein the magnetic field generating apparatus comprises an elevating device capable of moving up and down in a vertical direction.

15. A method for pulling a single crystal, comprising pulling a semiconductor single crystal using the single crystal pulling apparatus according to claim 7.

16. A method for pulling a single crystal, comprising pulling a semiconductor single crystal using the single crystal pulling apparatus according to claim 8.

17. A method for pulling a single crystal, comprising pulling a semiconductor single crystal using the single crystal pulling apparatus according to claim 9.

18. A method for pulling a single crystal, comprising pulling a semiconductor single crystal using the single crystal pulling apparatus according to claim 10.

19. A method for pulling a single crystal, comprising pulling a semiconductor single crystal using the single crystal pulling apparatus according to claim 11.

20. A method for pulling a single crystal, comprising pulling a semiconductor single crystal using the single crystal pulling apparatus according to claim 12.

21. A method for pulling a single crystal, comprising pulling a semiconductor single crystal using the single crystal pulling apparatus according to claim 13.

22. A method for pulling a single crystal, comprising pulling a semiconductor single crystal using the single crystal pulling apparatus according to claim 14.

23. The method for pulling a single crystal according to claim 15, wherein the semiconductor single crystal to be pulled is a defect-free region single crystal.
